(19) United States
(12) Patent Application Publication
(10) Pub. No.: US 2021/0119573 A1
(43) Pub. Date: Apr. 22, 2021

(54) ADAPTABLE SOLAR CONCENTRATOR

(71) Applicant: Pioneer Astronautics, Lakewood, CO (US)

(72) Inventor: Robert M. Zubrin, Lakewood, CO (US)

(21) Appl. No.: 17/072,274

(22) Filed: Oct. 16, 2020

Related U.S. Application Data
(60) Provisional application No. 62/916,195, filed on Oct. 16, 2019.

(51) Int. Cl. H02S 40/22; H02S 20/32; F24S 30/425; F24S 23/74; F24S 23/70; F24S 50/20; F24S 20/20; F24S 10/70

(52) U.S. Cl. CPC H02S 40/22; H02S 20/32; F24S 30/425; F24S 10/70; F24S 23/82; F24S 50/20; F24S 20/20; F24S 23/745

(57) ABSTRACT

Embodiments herein provide for a Concentrator photovoltaics (CPV) solution that can further lower the cost of CPV systems and enable a lower cost of electricity (LCOE). In one embodiment, a system includes a cylindrical reflective trough concentrator. The system also includes a photovoltaic receiver panel, with a receiver panel located on a swing arm having an axis of rotation at a center of the cylindrical reflective trough concentrator, wherein the swing arm is operable to move the photovoltaic receiver panel to track sunlight reflected from the cylindrical reflective trough concentrator as sun traverses the sky.

### CROSS REFERENCE TO RELATED APPLICATIONS

This patent application claims priority to, and thus the benefit of an earlier filing date from, U.S. Provisional Patent Application No. 62/916,195 (filed Oct. 16, 2019), which is hereby incorporated by reference.

### BACKGROUND

Concentrator photovoltaics (CPV) systems have been adopted more readily in utility power systems than in grid-tie commercial applications. Those CPV systems are generally all based on parabolic reflector designs.

Currently solar power provides 1.5% to the total annual electricity supply in the United States, and is projected to grow to 5% by 2030. While impressive when measured against past performance, this is still too small to make a substantial difference to goals such as combatting climate change or achieving American energy independence. The reason for this shortfall is that Earth based photovoltaic power is too expensive. While important gains have been made in recent years (e.g., reducing solar energy costs to $0.15 to $0.40 per kWh), this is still insufficient to compete with fossil fuels offering $0.04 to $0.12 per kWh. The cost of solar energy electricity needs to be lowered or it will remain a minor contributor to overall power generation.

In sharp contrast to photovoltaics' relatively minor role as a player in the energy market on Earth, they have long been overwhelmingly dominant in supplying power in space. Indeed, over 99 percent of all spacecraft ever launched have been powered by photovoltaic arrays. This is so because photovoltaics are relatively cheap, well understood, very reliable, have no moving parts, require no fuel, are long lasting, and pose no real or perceived launch safety risks to the public. Unfortunately, however, their dependence upon sunlight for their energy source makes photovoltaics much less attractive for missions to the outer solar system. For this reason, most outer solar system missions, including Pioneer Jupiter, Voyager, Galileo, Cassini, and New Horizons have used radioisotope thermoelectric generators (RTGs). While quite reliable, RTGs are very expensive and have been involved in litigation with groups opposed to their use. For this reason, it would be very attractive to expand the operating envelope of photovoltaics to include destinations in the outer solar system.

Furthermore, while adequate for providing power for spacecraft communications and internal functions, photovoltaic power systems need to be made lighter if they are to prove truly attractive for other applications, notably electric propulsion systems. Finally space-based solar power systems are quite expensive, as the cells need to be radiation-hardened and consequently can cost up to $250/watt, two orders of magnitude more than typical Earth-based systems.

Despite the fact that, measured in kilowatts, the terrestrial power market is tens of thousands of times larger than the space power market, the photovoltaic share of the space power market is two orders of magnitude higher than its terrestrial share, and space-hardened photovoltaics sell for two orders of magnitude more than terrestrial cells. These facts combine to create somewhat comparable size cash markets for photovoltaics on Earth and in space. As a result, many solar technology companies acquire a substantial fraction of their income from space applications, and the use of solar power in space has made major financial contributions to advancing solar technology on Earth. As a result, expanding the market for space solar power is quite relevant to the advancement of solar energy on Earth as well.

Thus, expansion of the use of solar energy to its full potential requires first and foremost a cheaper system for both Earth and space applications, as well as lighter systems capable of operating at both higher and lower sunlight intensities for use in space.

### SUMMARY

The embodiments herein provide for a CPV solution that can further lower the cost of CPV systems and therefore enable a lower cost of electricity (LCOE). In one embodiment, an Adaptable Solar Concentrator (ASC) system is based on relatively inexpensive cylindrical concentrator reflector optics to focus sunlight on a photovoltaic receiver. A tracking system is enabled by a circular geometry. For example, a relatively large circular arc of reflector optics are static (e.g., fixed to the ground) and only the receiver moves and tracks throughout the day the reflected concentrated sunlight by a rotation around its axis. The photovoltaic (PV) receiver, being substantially smaller and lighter than the concentrator optics, provides a lower overall tracking system costs and mass than traditional CPV parabolic systems through the use of smaller lower power motors instead of those required to move large and heavy parabolic reflectors of previous systems.

The ASC system is a low concentration CPV system which employs a fewer number of PV cells (e.g., modified for relatively low concentration) and it is intrinsically PV cell technology independent. That is, the ASC allows newer and upcoming, more efficient types of solar cells to be used in its PV receiver to further lower costs in the future.

Some advantages of the ASC system compared to other types of CPV systems include: (1) a cylindrical reflector that is much cheaper to fabricate than parabolic reflectors or Fresnel lenses; (2) low to moderate concentrations generally require no active cooling of PV cells; (3) the tracking system required is much smaller, lighter, and cheaper than conventional systems; (4) a superior acceptance angle (˜10°) when compared to conventional parabolic concentrators (typically <1%); and, (5) the ASC is PV technology independent system.

Silicon, thin-films, next generation low-cost tandems, and other low cost upcoming PV technologies (e.g., perovskites, organic, carbon based nano materials, and/or others can be used in the PV receiver of the ASC. These characteristics make the system cheaper to manufacture and easier to operate. As a result of these combined key competitive advantages, the ASC system embodiments herein can be developed to produce solar electricity at cheaper costs than any existing photovoltaic alternative by as much as a factor of three.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 illustrates a basic operating principle of an ASC system, in one exemplary embodiment.

FIG. 2 illustrates a method of tracking the Sun employed by the ASC.

FIG. 3 is a schematic view of an ASC.

FIGS. 4 and 5 illustrate the ASC in an exemplary east-west orientation.

FIGS. 6 and 7 illustrate varying an exemplary concentration of light received by the PV panel in an ASC.

FIGS. 8-10 illustrate various exemplary ASC receiver design alternatives.

### DETAILED DESCRIPTION OF THE FIGURES

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention and are to be construed as being without limitation to such specifically recited examples and conditions. As a result, the invention is not limited to the specific embodiments or examples described below.

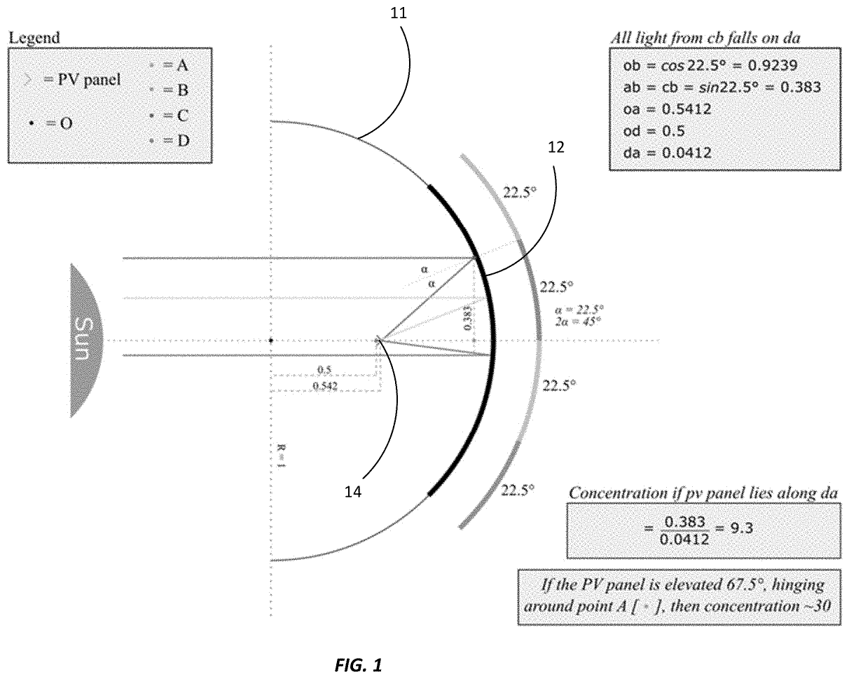

FIG. 1 illustrates a basic operating principle of an ASC system, in one exemplary embodiment. In the ASC system, an inexpensive cylindrical concentrator is used to focus sunlight on a photovoltaic receiver. One point of novelty lies with the simplicity of the tracking system enabled by the circular geometry. In the ASC, a large circular arc 11 of the reflector 12 optics are static (grounded) and only the receiver tracks 14 (by simple rotation) enabling the one-axis tracking. The PV receiver, being much smaller and lighter than the concentrator optics, allows lower overall tracker system costs than traditional CPV parabolic systems. While the cylindrical concentrator used by the ASC may not achieve the ˜thousand fold concentrations obtainable by a parabolic reflector, the ASC can achieve concentrations of up to 30λ, which is all that is needed, or in fact desired, if cheap silicon cells are to be used by the receiver.

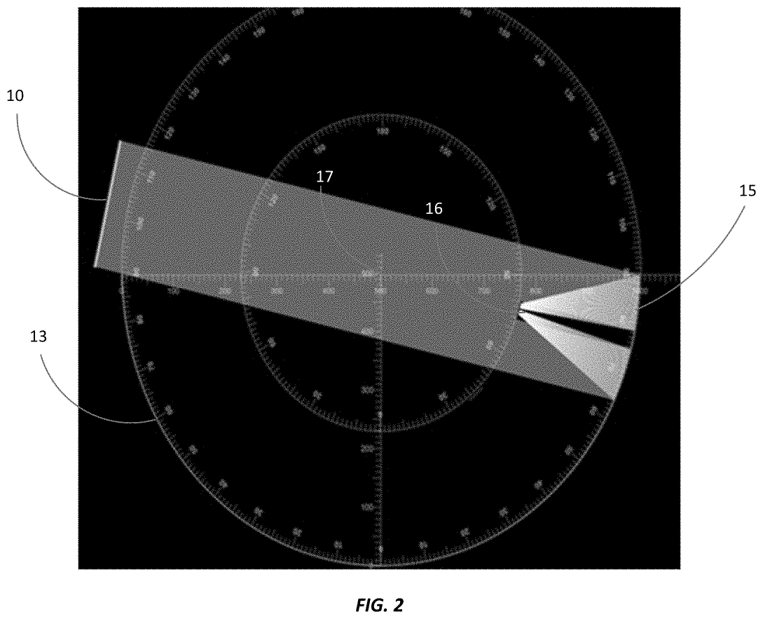

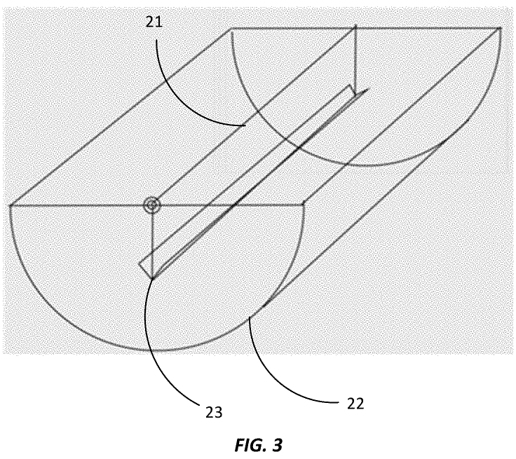

A method of tracking the Sun employed by the ASC is illustrated in FIGS. 2 and 3. For example, as shown in FIG. 3, a relatively small ASC photovolatic receiver 23 tracks the Sun by moving in a circular arc around the cylindrical concentrator reflector center line 21 while a much larger cylindrical concentrator reflector 22 remains stationary.

As shown in FIG. 2, if we imagine the center line 17 of the reflector trough running in the north-south direction (e.g., with the trough elevated at an angle equal to the local latitude) on the morning of the equinox, the Sun would be in the position represented by the line 10 at left around 6:30 AM, shining light on the region of the reflector 15 between 3 and 4 O'clock on the outer circle 13 at right, which focusses the light on the photovoltaic receiver 16, denoted at the 3:30 O'clock position on the inner circle at right. As the Sun moves clockwise to 12 O'clock at noon, the receiver tracks by moving to 6 O'clock, and so on, until at 6 PM the Sun sets in the 3 O'clock position at right while the receiver takes in its last light from the 9 O'clock position at left.

The advantage of this design is that instead of having to track the Sun with a large concentrator, as would be required if the concentrator were parabolic, by utilizing a cylindrical reflector only the small receiver needs to track. As this is an order of magnitude smaller than the concentrator optics, the mass and cost required for the tracking system are greatly reduced. Additionally, the cylindrical concentrator is much cheaper to manufacture than a parabolic concentrator, as it could be made by simply aluminizing the interior of a plastic tube, and cutting the tube lengthwise into quarters, or by aluminizing a plastic sheet and bending it into a circular arc. In addition, the moderate concentration (5× to 20×) of the ASC design allows the use of low-cost silicon cells, without any cooling system being required, although cooling could be used). Finally, a moderate concentration cylindrical reflector has an acceptance angle of about 20 degrees, versus 2 degrees for a parabolic contractor, making the required tolerances for manufacture and successful operation of the ASC much broader. A three-dimensional view of such a system is presented in FIG. 3.

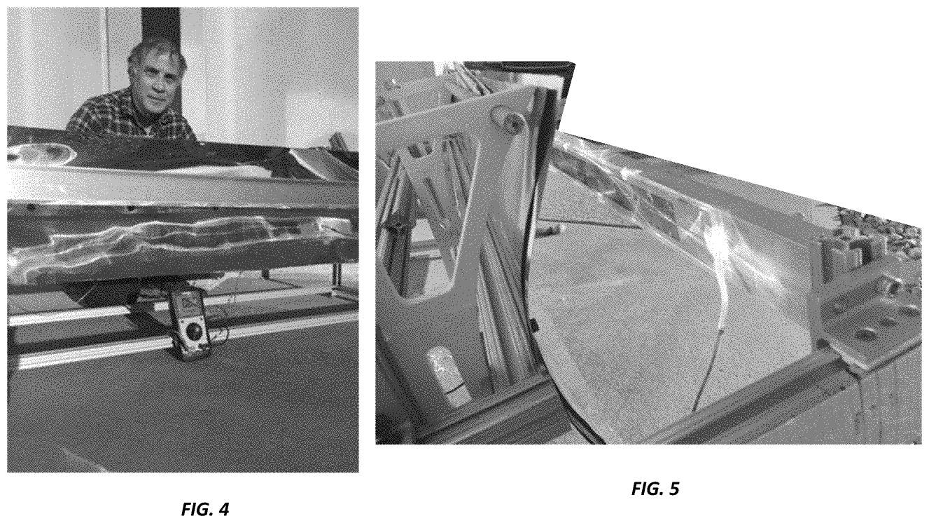

In the above example, it was assumed that the ASC concentrator optics are oriented in the north-south direction. This is possible, but it can alternatively be oriented in the east-west orientation, as illustrated in FIGS. 4 and 5. In this case, the receiver would remain stationary during the day, and only move slowly to change its position around the cylinder center in accord with the seasons, to orient itself to focus on the sun at high noon. Again, in this case, the trough would lie flat on the ground and not move, since if the receiver is positioned at the Sun's noon elevations, the Sun would be moving in the plane defined by the receiver 23 and the trough centerline 21 all day (see FIG. 3). In this case, the intensity of the sun as seen by the receiver would be that given by the concentration reduced by the cosine losses associated with the Sun's position in the sky. So, for example, if the ASC system had an ideal concentration ratio of 10, and it was 9 AM on the day of the solstice, with clear skies, the actual concentration of light at the receiver would be 7.07 suns, since the light would be hitting the trough at a 45 degree angle.

In one embodiment (see FIGS. 4. and 5), the ASC had a concentration ratio of 8× and the ASC employed an array of 14 off the shelf silicon cells, rated for a total output of 5 W in direct full equatorial noon sunlight. These embodiments exemplarily produced 40 W in late November Colorado sunlight at about 3 PM.

The ASC system also meets the needs for enhanced use of solar energy in space. For example, with concentrations as high as 30λ, ASC system embodiments herein could be used provide light flux at Jupiter (where sunlight is 3.7% as strong as it is on Earth) at slightly higher than normal terrestrial levels. Even at Saturn, where sunlight is only 1.1% as strong as it is on Earth, it could provide light flux equal to 33% terrestrial levels, or about the average prevailing at mid-latitudes on Mars, where solar energy has repeatedly been used with considerable success. Not only that, but by defocusing the ASC system, the same ASC system could be used on a spacecraft that travels close to the sun, for example on a Venus swing by maneuver, and then with greater and eventually full focus as it moves onward towards its outer solar system destination. Such ASC systems could also be used to advantage on the surface of the Moon, Mars, asteroids, and the moons of Jupiter and Saturn.

Methods of defocusing the ASC to allow the same unit to be used to be used in the inner solar system and the outer solar system (e.g., on a mission to Saturn that involves a Venus flyby along the way) include either moving the receiver PV panel away from or towards the concentrator, or hinging the receiver so that it receives the concentrated sunlight obliquely.

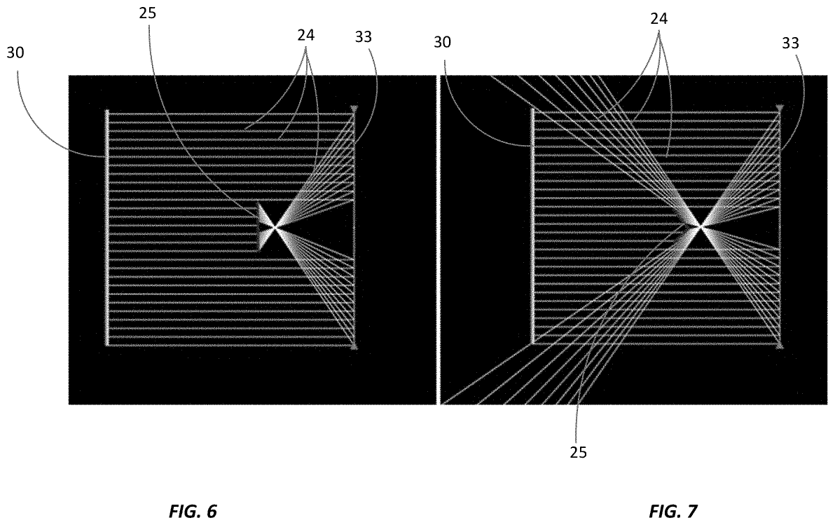

FIGS. 6 and 7 illustrate varying the concentration of the light received by the PV panel in an ASC. The light source 30 on the left, the concentrator mirror 33 is on the right. Light rays 24, starting at left are reflected by the mirror at right. The photovoltaic panels 25 are located just behind the focus near the center. FIG. 6 shows the ASC operating at full concentration with the photovoltaic panels deployed to catch all the sunlight in the outer solar system. And, FIG. 7 shows the system operating at reduced concentration with the photovoltaic panels folded back to miss most of the sunlight in the inner solar system.

As noted, space-rated solar cells are much more expensive than terrestrial cells, with prices as high as $250 for silicon cells per Watt, and much more still for gallium arsenide. The ASC's potential to reduce this cost, by replacing ultra-high cost rad-hardened cells with cheap reflectors would be welcomed by the spacecraft community.

Finally, as noted, the ASC offers many advantages for space applications because it promises to be much lighter than conventional systems. Existing spacecraft solar panels have a mass of about 4 kg per square meter, or 20 kg/kW at Earth's distance from the Sun. Since in space the reflector does not have to deal with weather, a very lightweight aluminized Mylar foil with a mass of 10 gm per square meter could be used for the concentrator, allowing the mass of the ASC power system with a concentration ratio of 10× or more to be cut by an order of magnitude. This is important, and not only because cutting mass on any spacecraft system is always welcome. For example, there are today new spacecraft propulsion technologies whose potential utilization is being sharply limited by the mass of existing power systems. This is particularly true for electric propulsion systems, which can readily obtain exhaust velocities ten times those of the best possible chemical rockets. However, despite this, such systems have thus far been limited to station keeping and other slow maneuvers because provision of the high power necessary for rapid acceleration would add too much mass to the spacecraft. But, if the mass per unit power of photovoltaic power systems could be sharply reduced, then the potential of electric propulsion systems to enable fast interplanetary travel (e.g., trips to Mars) could actually be realized and completely transform the prospects for the exploration and development of space.

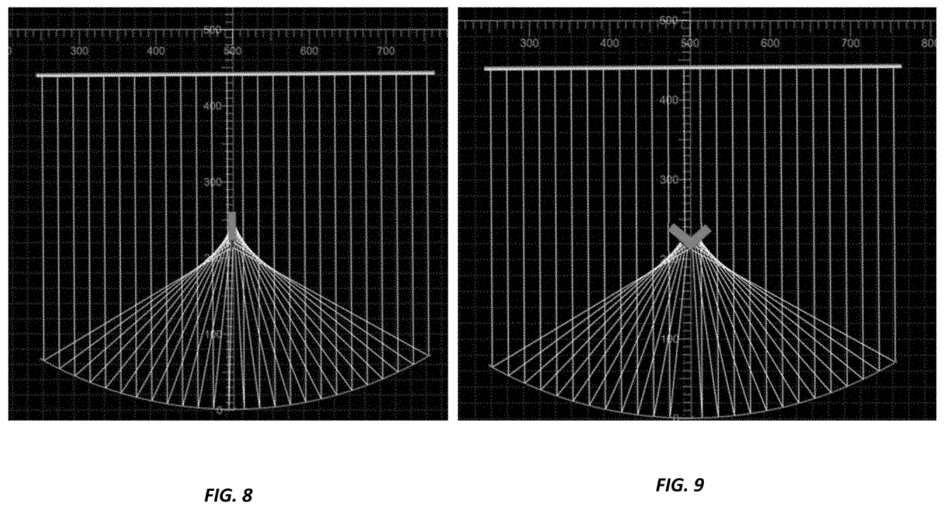

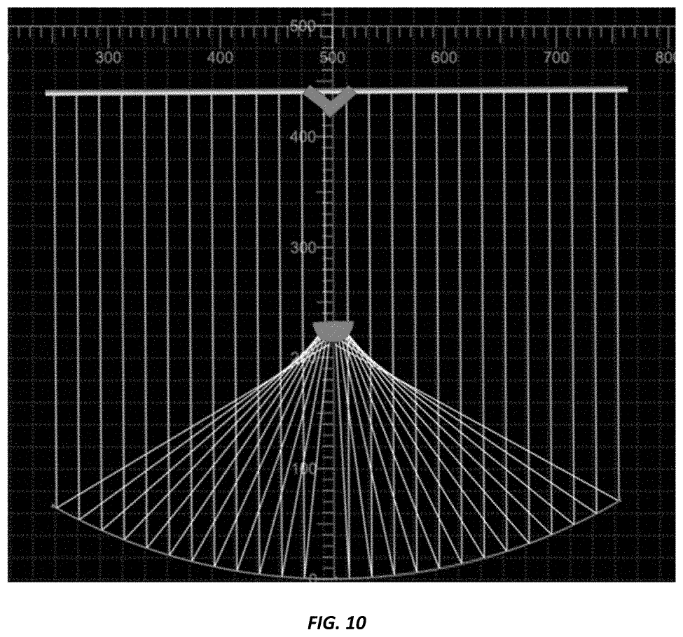

FIGS. 8-10 illustrate various ASC receiver design alternatives. For example, FIG. 8 illustrates an exemplary bifacial” vertical PV receiver where PV cells are back to back. Flat PV cells, such as Si, can also be used. FIG. 9 illustrates a “V-shape” PV receiver that improves PV cell illumination uniformity but still presents significant gradients. This embodiment may employ flat PV cells. And, FIG. 10 illustrates a “Circular arc” PV receiver where light has a normal incidence on the PV cells area. This embodiment may provide the best uniformity for cell illumination. This embodiment may also be flexible (e.g., bendable) and configured with light weight, high specific power (W/kg) thin-film PV cells, such as CIGS cells in stainless steel or polyimide (e.g., high temp plastic) substrates.

The ASC has a relatively high acceptance angle. For example, because of its moderate concentration, an ASC will have an acceptance angle that is much higher than is possible with a high concentration parabolic concentrator. This is because the maximum angle, ϕ, for a photovoltaic system with a concentration ratio C, operated in a medium with index of refraction n is given by:

Sin²ϕ=n²/C

Air has an index of refraction of about 1. So, an ASC with a concentration ratio of 9× would have an angle of acceptance of 19.5 degrees, while one with a concentration of 30× would have an angle of acceptance of 10.5 degrees. These are an order of magnitude larger than the ˜2 degree angle of acceptance typical of concentrated parabolic systems

The ASC also has high optical efficiency. For example, the optical efficiency ηₒₚ of a lens illuminated by a given light source can be defined as the fraction of radiant power at its input aperture Pᵢₙ which reaches its output Pₒᵤₜ. The efficiency can be expressed in terms of the average irradiance at the input lens aperture Gᵢₙ (θ, λ), the output irradiance at the lens focus Gₒᵤₜ (θ, λ), and the geometric concentration X_{geo}. The geometric concentration is defined as the ratio of the input area Aᵢₙ (i.e., area evaluated at the input aperture of the lens) to the output area Aₒᵤₜ (i.e., the area evaluated at the focal plane of the lens or, what is equivalent, the receiver area). Such is illustrated as follows:

$${η}_{op} = \frac{{P}_{out}}{{P}_{i n}} = \frac{{G}_{out} {A}_{out}}{{G}_{i n} {A}_{i n}} = \frac{{G}_{out}}{{G}_{i n} {X}_{geo}}$$

Assuming the reflectivity of materials in ASC optics are similar to materials used in state-of-the-art parabolic reflectors, the optical efficiency for the ASC will be higher than parabolic reflectors because the geometric concentration X_{geo} is low (e.g., 9×-30×) as compared to high concentration parabolic designs (>100×).

In considering concentrated photovoltaic power, one issue regards what the concentration ratio should be. At first glance, the highest possible concentration ratios might appear optimal because they minimize the required area of solar cells, which are far more expensive than concentrator material. However, as the concentration ratio increases beyond a certain point, additional requirements are levied on the solar cells, making them more expensive. One dramatic illustration of this was the failure involving the user of Fresnel lenses to concentrate solar energy 1000×. This required using advanced gallium-arsenide cells, whose cost at the time when they were developed was about 500 times that of common silicon cells. This still offered an apparent cost advantage to the design of a factor of two versus using silicon cells with unconcentrated light. However, when silicon cells prices dropped by a factor of two, the concept became unviable, as it had the same solar cell costs as unconcentrated silicon, but many extra costs associated with concentrators and related systems.

The cylindrical concentrators employed herein, however, can achieve concentration ratios as high as 30×. But, a more modest level (e.g., 6×-12×) may be best since (1) it relaxes the top contact grid designs of the PV cells; (2) requires no active cooling, and (3) can use readily available parts and components. Cheap silicon cells optimized for 7× concentration have also been developed and deployed with parabolic concentrators. By connecting small cells in series, voltage increases at the expense of amperage and off the shelf solar cells can be used at concentration ratios of at least 8×.

In some embodiments, a coolant may be used. For example, if water or another coolant is run through the rear side of ASC photovoltaic receiver panel, that coolant can be heated to elevated temperatures. Depending on the concentration ratio employed by the ASC, the hot coolant produced can be used for home heating, cooking, industrial purposes, or for generating additional electrical power.

Additionally, consider an north-south oriented ASC system, with a radius of 1 m, 5 m long. The PV receiver can take light from 60 degrees of arc, or 5 square meters of 1 sun illumination. At 20% efficiency this equals 1 kWe. At a concentration of 10λ, 0.5 square meters of PV cells are required. But, the total concentrator area of the ASC system embodiments herein may be about 16 m².

In some embodiments, the ASC system may be fully active from 8 AM through 4 PM, producing 8 kWh/day, or 2920 kWh per year. And, 1 kWe flat panels costing $1200/kWe would produce 6 kWh/day. Such 1 kWe modules could be sold in groups of 1-100 to homeowners, farms, and apartment buildings, in groups of 100 to 1000 to commercial customers, and in groups of 1000 or more to utilities. Manufacturers typically sell the units for $800/kWe, underselling the market by factor of 2. Thus, profit for a manufacturer would equal $400/kWe. At $0.10/kWh, the ASC system would repay the customer in 3 years. Under these circumstances, the use of solar energy could commercially accepted.

The public benefits of ASC system are manifold. First and foremost, the ASC system embodiments herein offer the potential to sharply drive down the cost of photovoltaic power, helping to make it fully competitive with fossil fuels. This is important if solar power is ever to replace as major fraction of fossil fuel use, and materially contribute to the reduction of global greenhouse gas and conventional pollutant emissions. And, if the price of solar energy can be sharply reduced, it will become a much more promising technology for bringing electricity. Some of ASC system embodiments herein are adaptable to smaller-scale modular designs and large-scale production suitable for a range of applications including household power, farm and off grid power, commercial power installations, large scale utility power, space power, etc.

Other advantages of the ASM system embodiments herein include:
combining a cylindrical arc receiver (CAR) concentrator with adaptable optics;
the use of a cylindrical trough concentrator greatly reduces required PV area;
cutting solar cell area and cost by up to a factor of 30 compared to non-concentrated systems;
the cylindrical trough concentrator of the ASC is generally much cheaper to manufacture than parabolic reflectors;
the cylindrical trough concentrator of the ASC can be constructed with readily available materials to achieve the circular arc shape;
the ASM system provides a higher “angle of acceptance” therefore reducing the cost of the tracker controller;
the cylindrical trough concentrator of the ASC allows tracking by a much smaller PV receiver instead of large reflector;
the ASC solves major issue with the cost of CPV tracker systems (e.g., the need to mechanically move large area and heavy reflectors to concentrate sunlight);
moderate concentration enables use of inexpensive PV solar cells without cooling systems;
the ASC reduces PV area cuts cost and mass of space solar power systems;
the cylindrical trough concentrator of the ASC can achieve a concentration ratio of ˜30;
the ASC is compatible with Si, CIGS, and GaAs cells;
the ASC is more forgiving than higher concentration optics;
the cylindrical trough concentrator of the ASC running east-west does not need to track Sun due to seasonal change;
the cylindrical trough concentrator of the ASC running north-south allows efficient daily tracking with a relatively simple 1 axis rotation system;
the cylindrical trough concentrator of the ASC can be rolled up, enhancing portable applications;
the elimination of a trough tracking system cuts costs;
adaptable optics maintain relatively constant power despite daily variation in solar flux;
the adaptable optics allow a same unit to be used across solar system, from Mercury to Neptune;
being lightweight, the ASC system can enhance electric propulsion and other space power applications; and
the ASC is cheaper, lighter, more portable, and more robust than other solar power alternatives.

Generally, the ASC is a practical concept that could help cheapen solar energy sufficiently make it fully competitive with fossil fuels. This is important to allowing solar energy to become a dominant source of power on Earth. It would also help enable the use of solar energy on space exploration missions that span the solar system. Finally, by making space solar power much lighter, the ASC could enable entirely new and revolutionary applications.

What is claimed is:

1. A system, comprising:
a cylindrical reflective trough concentrator; and
a photovoltaic receiver panel being located on a swing arm having an axis of rotation at a center of the cylindrical reflective trough concentrator, wherein the swing arm is operable to move the photovoltaic receiver panel to track sunlight reflected from the cylindrical reflective trough concentrator as sun traverses the sky.

2. The system of claim 1, wherein:
the photovoltaic receiver panel is hinged so as to vary the intensity of the light received.

3. The system of claim 1, wherein:
the cylindrical reflective trough concentrator is plastic coated with a reflective material.

4. The system of claim 1, wherein:
the cylindrical reflective trough concentrator comprises sheet metal configured from at least one of aluminum or steel.

5. The system of claim 1, wherein:
the cylindrical reflective trough concentrator comprises a solar sail material including at least one of aluminized Mylar or nylon.

6. The system of claim 1, wherein:
the cylindrical reflective trough concentrator is inflatable

7. The system of claim 1, wherein:
the cylindrical reflective trough concentrator is oriented in a north-south direction, and tilted up at an angle equal to a local latitude such that sunlight is normal to a centerline of the cylindrical reflective trough concentrator at noon of equinox.

8. The system of claim 1, wherein:
the cylindrical reflective trough concentrator is oriented in an east-west direction and pointed such that a plane including a centerline and a cylinder axis of the cylindrical reflective trough concentrator is elevated at an angle equal to a local latitude.

9. The system of claim 7, wherein:
the photovoltaic receiver panel moves to track sun as the sun moves across sky from sunrise to sunset.

10. The system of claim 8, wherein:
the photovoltaic receiver panel moves to track a plane of ecliptic as the ecliptic changes its elevation in sky from wither solstice to summer solstice.

11. The system of claim 1, wherein:
the photovoltaic receiver panel is configured with silicon solar cells.

12. The system of claim 1, wherein:
the photovoltaic receiver panel is configured with copper indium gallium selenide solar cells.

13. The system of claim 1, wherein:
the photovoltaic receiver panel is configured with gallium arsenide solar cells.

14. The system of claim 1, wherein:
the cylindrical reflective trough concentrator comprises a concentration ratio between 1 and 50.

15. The system of claim 14, wherein:
the concentration ratio is between 5 and 30.

16. The system of claim 1, wherein:
the photovoltaic receiver panel is configured with coolant such that hot coolant is produced and used to provide thermal energy for at least one of home heating, office heating, cooking, industrial uses, or generation of power.

18. The system of claim 1, wherein:
a concentration of sunlight is used to enable production of solar energy in an outer solar system.

19. The system of claim 1, wherein:
the cylindrical reflective trough concentrator is configured to be substantially lightweight to allow for generation of electrical power at lower weight.

21. The system of claim 1, wherein:
an angle of acceptance of the cylindrical reflective trough concentrator is greater than 10 degrees.

22. The system of claim 1, wherein:
the cylindrical reflective trough concentrator is flexible.
